(19) United States
(12) Patent Application Publication
(10) Pub. No.: US 2026/0015766 A1
(43) Pub. Date: Jan. 15, 2026

(54) REACTION APPARATUS AND METHODS FOR DEPOSITING AN EPITAXIAL LAYER ON A SEMICONDUCTOR STRUCTURE WITH SIDE INJECTION

(71) Applicant: GlobalWafers Co., Ltd., Hsinchu (TW)

(72) Inventors: Chieh Hu, Chiayi City (TW); Chun-Chin Tu, Zhubei City (TW); Liang-Chin Chen, Zhubei City (TW); Wei-Jie Lin, Zhubei City (TW); Phuoc Ba Le, Taoyuan City (TW); Jyh-Chen Chen, Taoyuan City (TW)

(21) Appl. No.: 19/254,530

(22) Filed: Jun. 30, 2025

Related U.S. Application Data
(60) Provisional application No. 63/669,893, filed on Jul. 11, 2024.
(60) Provisional application No. 63/669,880, filed on Jul. 11, 2024.

(51) Int. Cl. C30B 25/14; C30B 25/08; C30B 25/10; H01L 21/02

(52) U.S. Cl. CPC C30B 25/14; C30B 25/08; C30B 25/10; H01L 21/02532; H01L 21/0262

(57) ABSTRACT

A reaction apparatus for depositing an epitaxial layer on a semiconductor structure. The reaction apparatus includes a first gas inlet for channeling a first process gas into the reaction chamber in a first direction. The reaction apparatus includes a second gas inlet for channeling a second process gas into the reaction chamber in a second direction. The first direction and second direction form an angle of between 45° and 75°.

### CROSS-REFERENCE TO RELATED APPLICATION

This application claims the benefit of U.S. Provisional Patent Application No. 63/669,880, filed Jul. 11, 2024, and claims the benefit of U.S. Provisional Patent Application No. 63/669,893 filed Jul. 11, 2024. Both applications are incorporated herein by reference it their entirety.

### FIELD OF THE DISCLOSURE

The field of the disclosure relates to reaction apparatus for depositing an epitaxial layer on a semiconductor structure with side injection of gas in the reaction chamber and to methods for depositing epitaxial layers that use side injection of gas.

### BACKGROUND

Epitaxial chemical vapor deposition (CVD) is a process for growing a thin layer of material on a semiconductor structure. Epitaxial CVD is widely used in semiconductor wafer production to build up epitaxial layers such that devices can be fabricated directly on the epitaxial layer. The epitaxial deposition process involves contacting a vaporous silicon source gas, such as silane or a chlorinated silane, with the front surface of the structure to deposit and grow an epitaxial layer of silicon on the front surface. A back surface opposite the front surface of the susceptor may be simultaneously contacted with hydrogen gas. The susceptor, which supports the semiconductor wafer in the deposition chamber during the epitaxial deposition, is rotated during the process to allow the epitaxial layer to grow evenly.

Customer specifications for integrated circuit substrates often specify an ultra-flat epitaxial surface. In 300 mm substrate processing, because of flatness specifications at the wafer radius from 120 mm to 148 mm, the epitaxy deposition rate is carefully controlled and adjusted to achieve a larger useable edge area. A need exists for apparatus and methods that control the silicon deposition slope profile near the edge of the wafer.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a reaction apparatus for depositing an epitaxial layer on a semiconductor structure. The reaction apparatus includes an upper dome and a lower dome attached to the upper dome. The upper dome and the lower dome define a reaction chamber. The apparatus includes an upper liner and a lower liner positioned below the upper liner. The upper liner and the lower liner define a first gas inlet for channeling a first process gas into the reaction chamber in a first direction. The apparatus includes a second gas inlet for channeling a second process gas into the reaction chamber in a second direction. The first direction and second direction form an angle of between 45° and 75°.

Another aspect of the present disclosure is directed to a method for depositing an epitaxial layer on a semiconductor structure in a reaction apparatus. The reaction apparatus includes an upper dome and a lower dome attached to the upper dome. The upper dome and the lower dome define a reaction chamber. The apparatus includes an upper liner and a lower liner positioned below the upper liner. A first process gas is directed through a first gas inlet defined by the upper liner and the lower liner. The first gas inlet channels the first process gas into the reaction chamber in a first direction. A second process gas is directed through a second gas inlet. The second gas inlet channels the second process gas into the reaction chamber in a second direction. The first direction and second direction form an angle of between 45° and 75°. The first process gas is contacted with the semiconductor structure to deposit an epitaxial layer on the semiconductor structure.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a front view of a reactor apparatus for depositing an epitaxial layer on a semiconductor substrate.

FIG. 2 is a perspective view of the reactor apparatus.

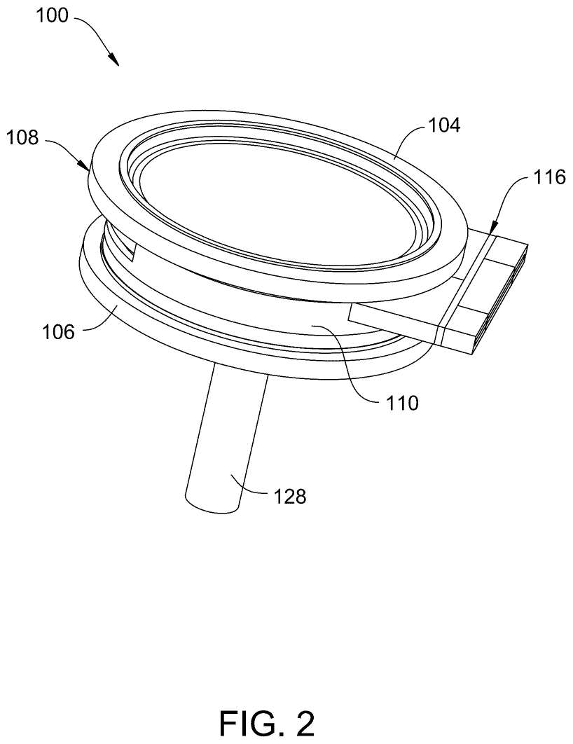

FIG. 3 is a cross sectional view of the reactor apparatus.

FIG. 4 is a perspective view of the reactor apparatus with the upper dome and upper liner removed for clarity and portions of the apparatus shown as transparent for clarity.

FIG. 5 is a perspective view of the reactor apparatus with the upper and lower domes removed to show first and second process gas inlets.

FIG. 6 is a top view of the reactor apparatus with the upper and lower domes removed to show first and second process gas inlets.

FIG. 7 shows the hydrogen streamline total flux and molar concentration for the reactor apparatus.

FIG. 8 shows the hydrogen chloride streamline total flux and molar concentration for the reactor apparatus.

FIG. 9 shows the trichlorosilane streamline total flux and molar concentration for the reactor apparatus.

FIG. 10 is the simulated offset thickness for epitaxial structures grown with different flow rates of hydrogen chloride and hydrogen.

FIG. 11 is the simulated offset thickness for epitaxial structures grown with use of a second gas inlet that is angled about 60° relative to the first inlet direction.

### DETAILED DESCRIPTION

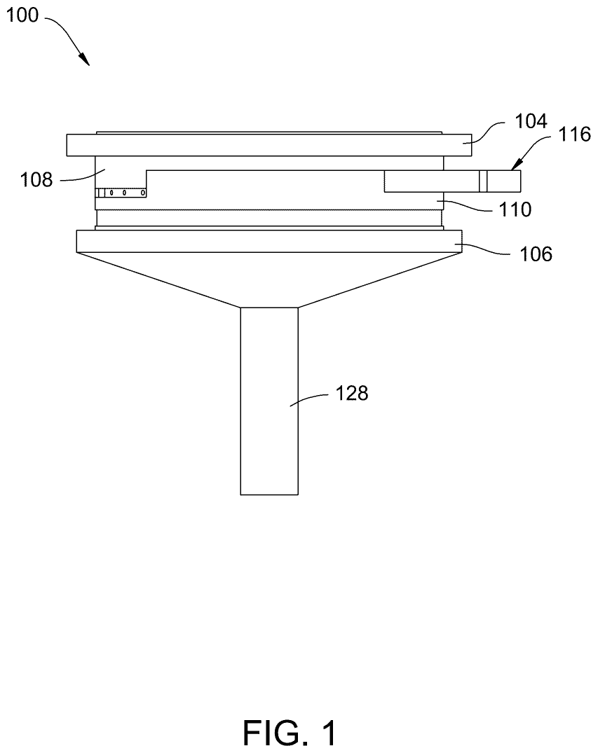

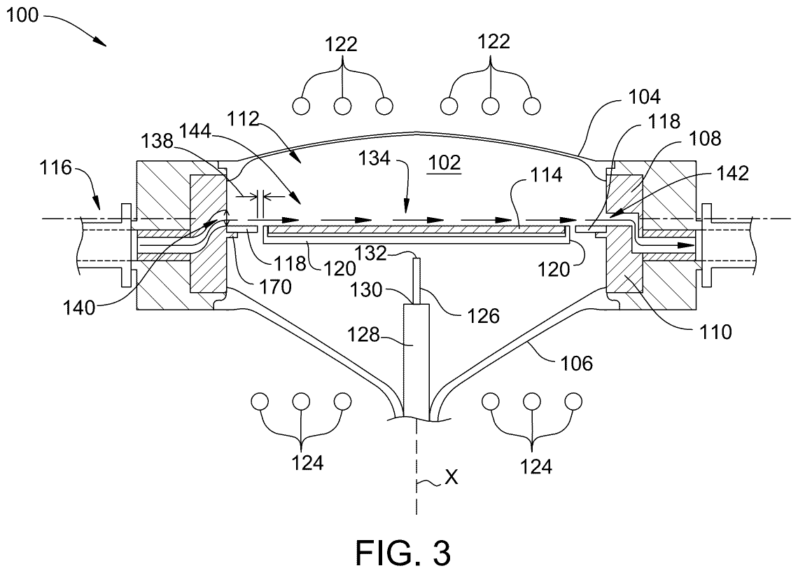

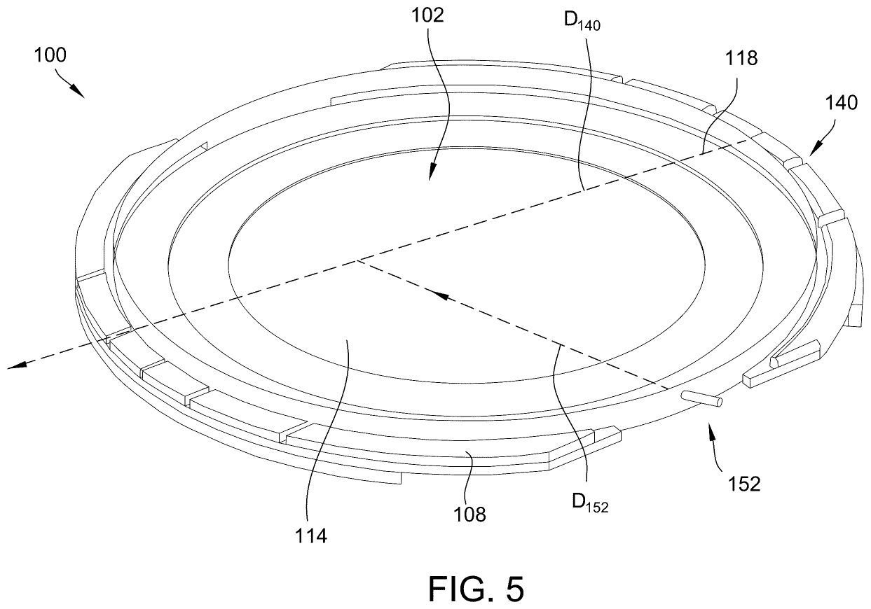

Referring now to FIG. 1, a reaction apparatus for depositing an epitaxial layer on a semiconductor substrate in accordance with embodiments of the present disclosure is generally referred to as “100”. The illustrated apparatus is a single wafer reactor (i.e., a 300 mm AMAT Centura reactor); however, the apparatus and methods disclosed herein for depositing an epitaxial layer are suitable for use in other reactor designs. The apparatus 100 includes an upper dome 104 and a lower dome 106 that define a reaction chamber 102 (FIG. 3). The apparatus 100 also includes an upper liner 108 and a lower liner 110. Collectively, the upper dome 104, lower dome 106, upper liner 108, and lower liner 110 define an interior space 112 of the reaction chamber 102 in which a process gas contacts a semiconductor structure 114. As discussed further below, a gas manifold 116 is used to direct a first process gas into the reaction chamber 102 through a first gas inlet 140 and a second process gas is directed ingot the reaction chamber 102 through a second gas inlet (FIG. 5).

The apparatus 100 may be used to process a semiconductor structure by depositing material on a semiconductor structure by a chemical vapor deposition (CVD) process, such as epitaxial CVD or polycrystalline CVD. In this regard, reference herein to epitaxy and/or CVD processes should not be considered limiting as the apparatus 100 may also be used for other purposes such as to perform etching or smoothing processes on the wafer. Also, the semiconductor structure shown herein is generally circular in shape, though structures of other shapes are contemplated within the scope of this disclosure. In some embodiments, the semiconductor structure on which the epitaxial layer is deposited is a single crystal silicon wafer.

Referring now to FIG. 3, within the interior space 112 of the reaction chamber 102 is a preheat ring 118 for heating the first process gas prior to contact with a semiconductor structure 114. The outside circumference of the preheat ring 118 is attached to the inner circumference of the lower liner 110. For example, the preheat ring 118 may be supported by an annular ledge 170 of the lower liner 110. A susceptor 120 traverses the space interior to the preheat ring 118 and supports the semiconductor structure 114.

Process gas may be heated prior to contacting the semiconductor structure 114. Both the preheat ring 118 and the susceptor 120 are generally opaque to absorb radiant heating light produced by high intensity lamps 122, 124 that may be located above and below the reaction chamber 102. Maintaining the preheat ring 118 and the susceptor 120 at a temperature above ambient allows the preheat ring 118 and the susceptor 120 to transfer heat to the process gas as the process gas passes over the preheat ring and the susceptor. Typically, the diameter of the semiconductor structure 114 is less than the diameter of the susceptor 120 to allow the susceptor to heat the process gas before it contacts the wafer.

The preheat ring 118 and susceptor 120 may suitably be constructed of opaque graphite coated with silicon carbide, though other materials are contemplated. The upper dome 104 and lower dome 106 are typically made of a transparent material to allow radiant heating light to pass into the reaction chamber 102 and onto the preheat ring 118 and the susceptor 120. The upper dome 104 and lower dome 106 may be constructed of transparent quartz. Quartz is generally transparent to infrared and visible light and is chemically stable under the reaction conditions of the deposition reaction. Equipment other than high intensity lamps 122, 124 may be used to provide heat to the reaction chamber such as, for example, resistance heaters and inductive heaters. An infrared temperature sensor (not shown) such as a pyrometer may be mounted on the reaction chamber 102 to monitor the temperature of the susceptor 120, preheat ring 118, or semiconductor structure 114 by receiving infrared radiation emitted by the susceptor, preheat ring, or wafer.

The apparatus 100 includes a shaft 126 that may support the susceptor 120. The shaft 126 extends through a central column 128. The shaft 126 includes a first end 130 attached to the central column 128 and a second end 132 positioned proximate a center region 134 of the semiconductor structure 114.

The shaft 126 is connected to a suitable rotation mechanism (not shown) for rotating the shaft 126, susceptor 120, and semiconductor structure 114 about a longitudinal axis X with respect to the apparatus 100. The outside edge of the susceptor 120 and inside edge of the preheat ring 118 are separated by a gap 138 to allow rotation of the susceptor. The semiconductor structure 114 is rotated to prevent an excess of material from being deposited on the wafer leading edge and provide a more uniform epitaxial layer.

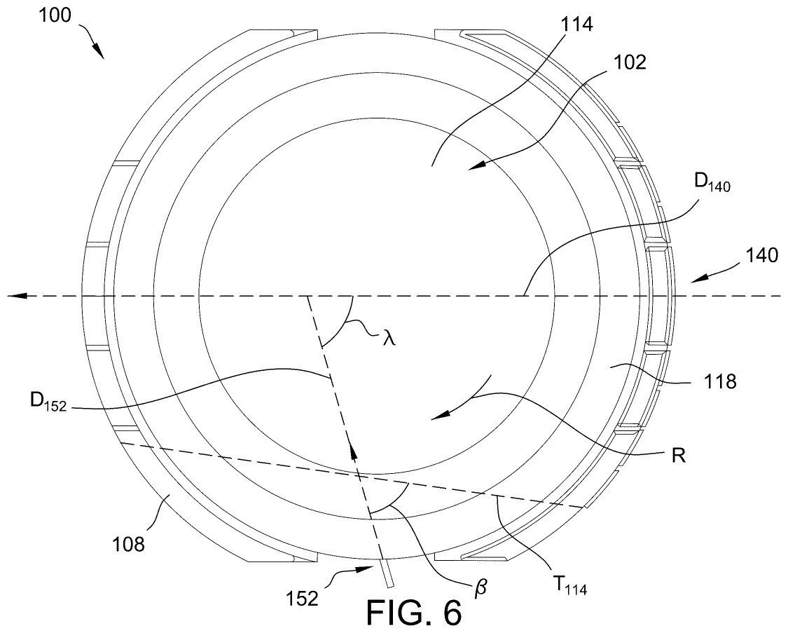

The preheat ring 118 modifies or tunes the first process gas prior to contact with the semiconductor structure 114 in order to improve the growth rate on the semiconductor wafer and create a more uniform radial deposition profile. The upper liner 108 and the lower liner 110 define a first gas inlet 140 and a process gas outlet 142. The first gas inlet 140 channels the first process gas into the reaction chamber 102 in a first direction D₁₄₀ (FIG. 5-6). The first process gas passes through the process gas outlet 142 where it is channeled out of the reaction chamber 102. The first process gas is channeled from the first gas inlet 140 to the process gas outlet 142 within the reaction chamber 102 as the semiconductor structure 114 is rotated within the reaction chamber.

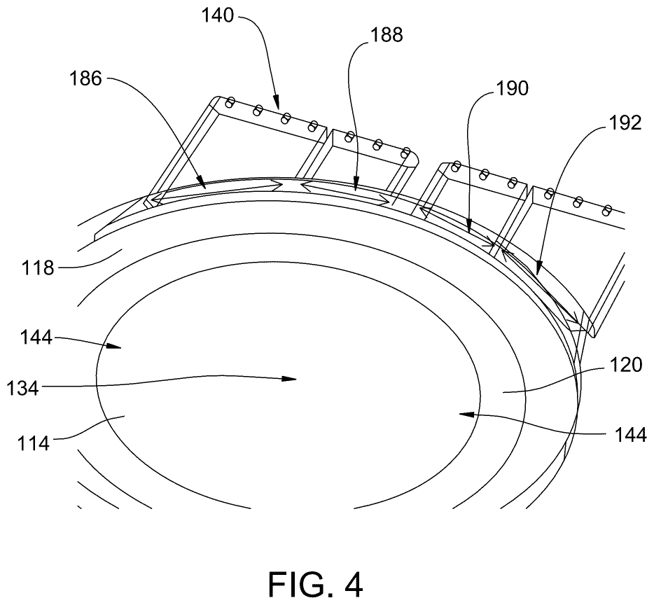

The first gas inlet 140 may be separated into inlet segments 186, 188, 190, 192 (FIG. 4). Each inlet segment 186, 188, 190, 192 channels process gas to a different portion of the semiconductor structure 114. For example, as illustrated in FIG. 4, the upper liner 108 and the lower liner 110 define a first inlet segment 186 that channels first process gas to an edge 144 of the semiconductor structure 114, a second inlet segment 188 that channels first process gas to the center region 134 of the semiconductor structure 114, a third inlet segment 190 that also channels the first process gas to the center region 134 of the semiconductor structure 114, and a fourth inlet segment 192 that channels the first process gas to the edge 144 of the semiconductor structure 114.

In some embodiments, the pressure inside the reaction chamber 102 is about atmospheric (i.e., atmospheric pressure chemical vapor deposition or “APCVD”). Other pressures in the reaction chamber 102 may be used including vacuum or pressure CVD systems. In some embodiments, the epitaxial layer (e.g., silicon) is deposited using metalorganic chemical vapor deposition (MOCVD), physical vapor deposition (PVD), low pressure chemical vapor deposition (LPCVD), plasma enhanced chemical vapor deposition (PECVD), reduced pressure chemical vapor deposition (RPCVD), or molecular beam epitaxy (MBE).

Referring now go FIGS. 5-6, the reaction apparatus 100 includes a second gas inlet 152 for channeling a second process gas into the reaction chamber 102. The first and second process gasses may have different compositions or may have the same composition as discussed further below.

The second gas inlet 152 channels the second process gas into the reaction chamber 102 in a second direction D₁₅₂. The first direction and the second direction form an angle λ of between 45° and 75°. In other embodiments, the first direction and second direction form an angle λ of between 50° and 70°, or between 55° and 65°, or an angle λ of about 60°. In this regard, the angle λ of the first and second directions specified herein is an azimuthal angle (i.e., the angle λ as viewed from above such as the angle shown in FIG. 6 which is given with respect to a longitudinal central axis of the reaction apparatus).

In the illustrated embodiment, the second gas inlet 152 is an injection nozzle such as nozzle having a relatively small diameter such as less than 10 mm.

To deposit an epitaxial layer on the semiconductor structure 114, the first process gas is directed through the first gas inlet 140 along the first direction D₁₄₀. The first process gas includes a silicon-containing gas such as methyl silane, silicon tetrahydride (silane), trisilane, disilane, pentasilane, neopentasilane, tetrasilane, dichlorosilane (SiH₂Cl₂), trichlorosilane (SiHCl₃), silicon tetrachloride (SiCl₄), among others. For example, silicon may be deposited by pyrolyzing silane (SiH₄) in a temperature range between about 550° C. and about 690° C., such as between about 580° C. and about 650° C. The chamber pressure may range from about 70 to about 400 mTorr. In other embodiment, the silicon-containing gas is trichlorosilane and deposition temperatures may range from about 1080° C. to about 1150° C. with the pressure being about atmospheric. The silicon-containing gas may be mixed with a carrier gas such as hydrogen (e.g., trichlorosilane in hydrogen). The concentration of the gas may be determined based on the desired deposition effects (e.g., deposition rate).

In some embodiments, the first process gas also includes hydrogen chloride which can reduce the deposition rate.

In some embodiments of the present disclosure, the second process gas that is directed through the second inlet 152 includes hydrogen, hydrogen chloride and trichlorosilane. In other embodiments, a different composition of gas (relative to the first process gas) may be used.

The first process gas contacts the top surface of the semiconductor structure causing a silicon epitaxial layer to deposit on the structure by the reversible equation (1):

$$TCS + {H}_{2} ↔ Si + 3 HCl \qquad ( eq . 1 )$$

Any suitable thickness of epitaxial layer may be achieved during deposition such as between 1 μm and 4 μm.

The semiconductor structure 114rotates clockwise (e.g., 10 to 100 RPM) as shown by the arrow R in FIG. 6. In this manner, the tangent T₁₁₄ of the semiconductor structure 114 (when intersecting D₁₅₂) forms an acute angle β with the direction D₁₅₂ of the second process gas as the semiconductor structure 114 approaches the direction D₁₅₂ of the second process gas (i.e., the second process gas moves more with the semiconductor structure rather than against the structure as the structure rotates).

The second process gas is introduced into the reaction chamber 102 through the second inlet 152 while the first process gas is introduced through the first inlet 140. The second process gas influences the chemical flux toward the edge of the semiconductor structure and increases the useable area of the semiconductor structure. The temperature and hydrogen flow rate of the second process gas may be used to tune the deposition profile on the semiconductor structure.

In some embodiments, the height of the second inlet 152 (i.e., the inlet nozzle) relative to the semiconductor structure 114 is altered to affect the deposition profile. Controlling the height of the second inlet 152 changes the hydrogen chloride and hydrogen gas flow rate across the semiconductor structure to control the wafer edge deposition rate. The height of the inlet 152 may be changes by selecting and installing a nozzle from a plurality of nozzles which are disposed at different heights relative to the susceptor.

### EXAMPLES

The processes of the present disclosure are further illustrated by the following Examples. These Examples should not be viewed in a limiting sense.

### Example 1: Streamline Total Flux and Molar Concentration

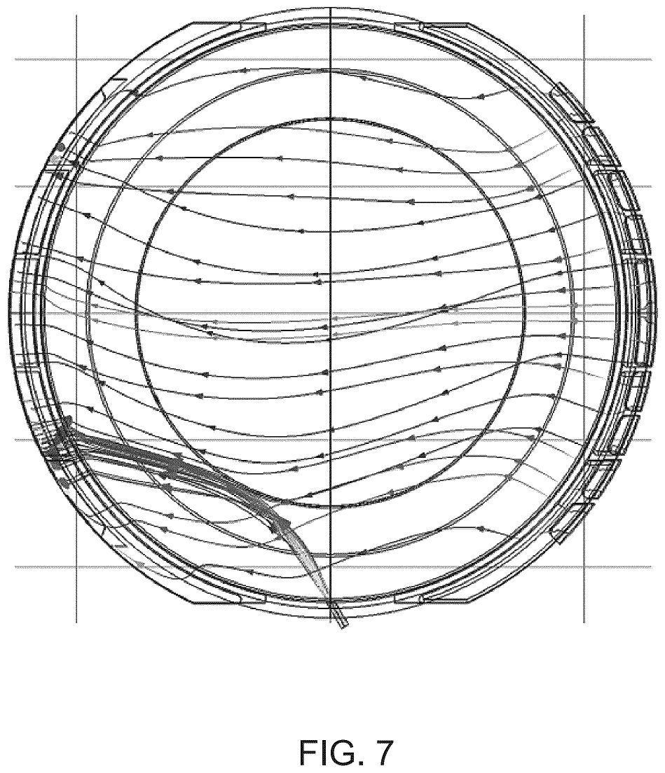

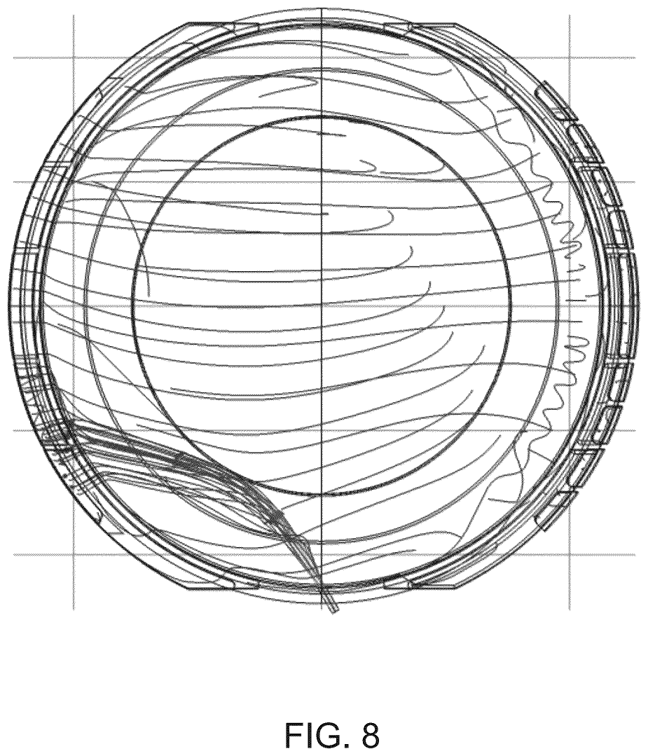

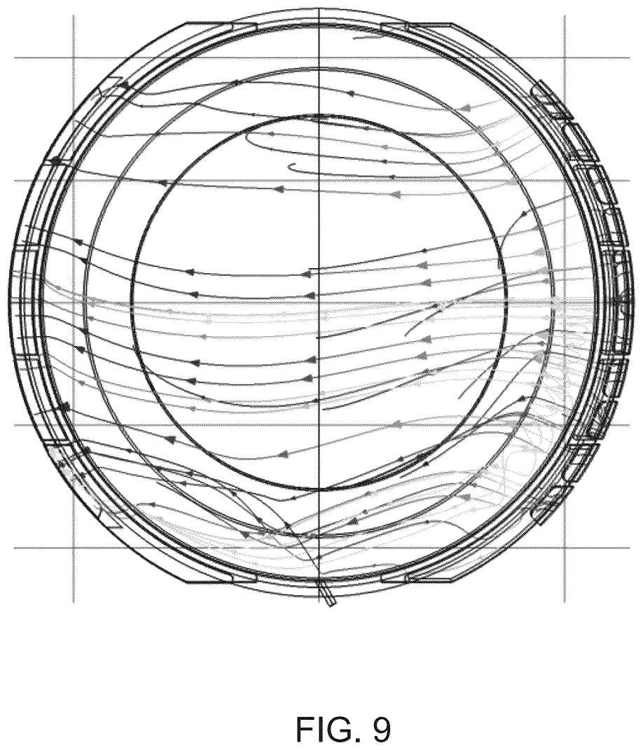

For the reactor of FIGS. 5-6, the main flow in first inlet 140 includes hydrogen gas and trichlorosilane for silicon thin film deposition. Hydrogen chloride and hydrogen are injected into the gas through the second inlet 152. The computer fluid dynamic with a chemical reaction are used to determine total chemical flux and streamlined to control the deposition profile on the silicon wafer. The hydrogen streamline total flux and molar concentration are shown in FIG. 7. The hydrogen chloride streamline total flux and molar concentration are shown in FIG. 8. The trichlorosilane streamline total flux and molar concentration are shown in FIG. 9.

As shown in FIG. 9, the trichlorosilane flux streamline touches the wafer edge which results in trichlorosilane affecting the wafer edge deposition profile.

### Example 2: Effect of Hydrogen on Offset Thickness

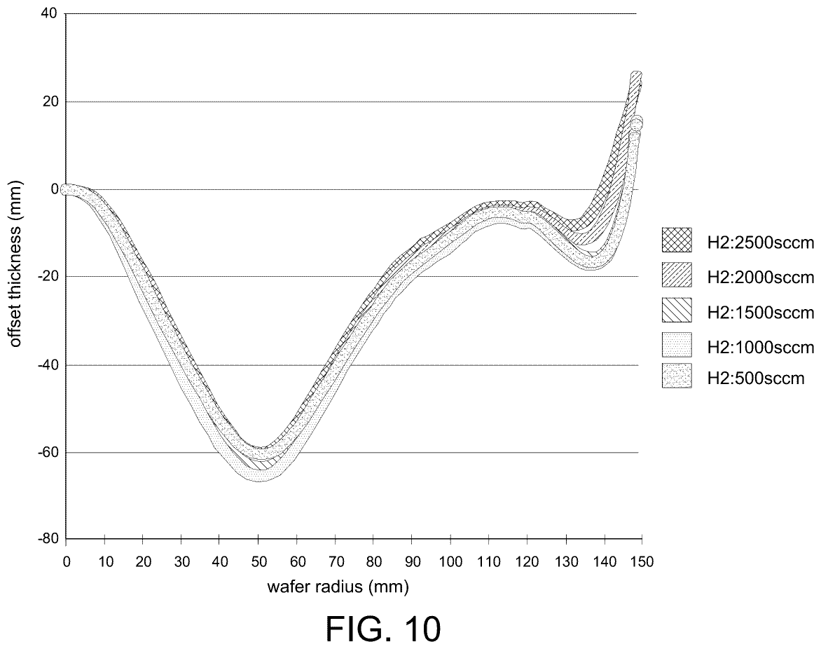

The hydrogen flow rate was varied from 500 sccm to 2500 sccm of hydrogen. The simulated offset thickness is shown in FIG. 10. The slope of the deposition thickness at r=90 mm to 120 mm is positive, and the slope at r=120 mm to 140 mm is negative.

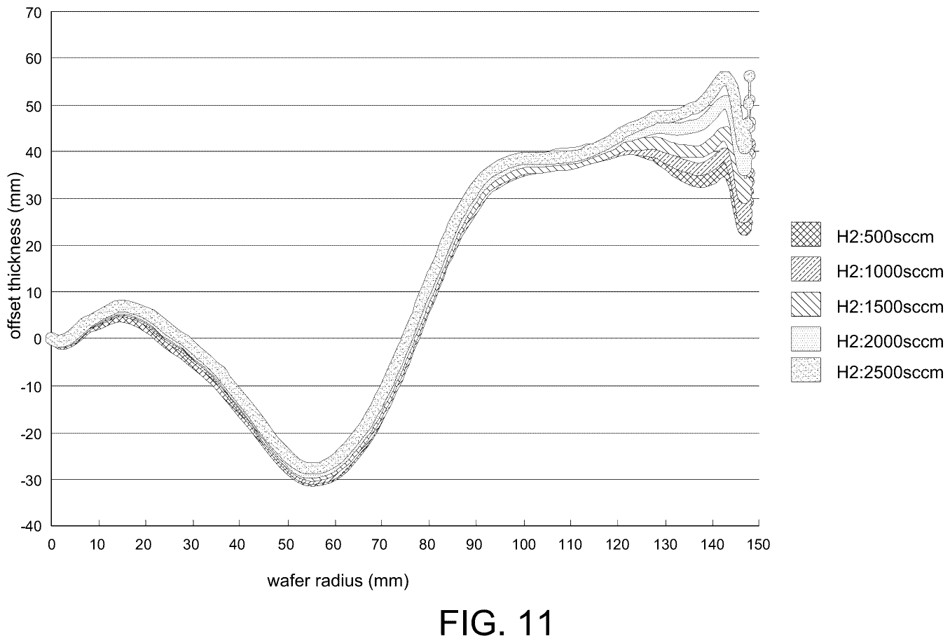

The hydrogen flow rate through the second inlet was varied from 500 sccm to 2500 sccm for the reactor of FIGS. 5-6. The simulated offset thickness is shown in FIG. 11. As shown in FIG. 11, the near edge profile rises with increasing hydrogen flow through the second inlet. From a hydrogen flow rate of 500 sccm to 2500 sccm, a profile increase between r=140 to r=145 mm is observed which affects the edge roll-off at the 148 mm radial position.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A reaction apparatus for depositing an epitaxial layer on a semiconductor structure, the reaction apparatus comprising:
an upper dome;
a lower dome attached to the upper dome, the upper dome and the lower dome defining a reaction chamber;
an upper liner;
a lower liner positioned below the upper liner, the upper liner and the lower liner defining a first gas inlet for channeling a first process gas into the reaction chamber in a first direction; and
a second gas inlet for channeling a second process gas into the reaction chamber in a second direction, the first direction and second direction forming an angle of between 45° and 75°.

2. The reaction apparatus as set forth in claim 1 wherein the first direction and second direction form an angle of between 50° and 70°.

3. The reaction apparatus as set forth in claim 1 wherein the first direction and second direction form an angle of between 55° and 65°.

4. The reaction apparatus as set forth in claim 1 wherein the first direction and second direction form an angle of about 60°.

5. The reaction apparatus as set forth in claim 1 further comprising a preheat ring positioned within the reaction chamber for heating the first process gas prior to the first process gas contacting the semiconductor structure.

6. The reaction apparatus as set forth in claim 1 comprising a gas outlet opposite the first gas inlet.

7. The reaction apparatus as set forth in claim 1 wherein the second gas inlet is an injection nozzle.

8. The reaction apparatus as set forth in claim 7 wherein the injection nozzle has a diameter of less than 10 mm.

9. The reaction apparatus as set forth in claim 1 wherein the first gas inlet comprises a first inlet segment, a second inlet segment, a third inlet segment, and a fourth inlet segment.

10. A method for depositing an epitaxial layer on a semiconductor structure in a reaction apparatus, the reaction apparatus comprising an upper dome, a lower dome attached to the upper dome, the upper dome and the lower dome defining a reaction chamber, an upper liner, and a lower liner positioned below the upper liner, the method comprising:
directing a first process gas through a first gas inlet defined by the upper liner and the lower liner, the first gas inlet channeling the first process gas into the reaction chamber in a first direction;
directing a second process gas through a second gas inlet, the second gas inlet channeling the second process gas into the reaction chamber in a second direction, the first direction and second direction forming an angle of between 45° and 75°; and
contacting the first process gas with the semiconductor structure to deposit an epitaxial layer on the semiconductor structure.

11. The method as set forth in claim 10 wherein the second process gas comprises a silicon-containing compound.

12. The method as set forth in claim 11 wherein the silicon-containing compound is trichlorosilane.

13. The method as set forth in claim 11 wherein the second process gas comprises hydrogen.

14. The method as set forth in claim 11 wherein the second process gas comprises hydrogen chloride.

15. The method as set forth in claim 11 wherein the first process gas comprises a silicon-containing compound, hydrogen, and hydrogen chloride.

16. The method as set forth in claim 15 wherein the silicon-containing compound is trichlorosilane.

17. The method as set forth in claim 10 comprising rotating the semiconductor structure within the reaction chamber.

18. The method as set forth in claim 10 wherein the first direction and the second direction form an angle of between 50° and 70°.

19. The method as set forth in claim 10 wherein the first direction and second direction form an angle of between 55° and 65°.

20. The method as set forth in claim 10 wherein the first direction and second direction form an angle of about 60°.
